(19) United States
(12) Patent Application Publication
(10) Pub. No.: US 2015/0098222 A1
(43) Pub. Date: Apr. 9, 2015

(54) Heat Sink

(71) Applicant: On-Q LLC, Oakland, CA (US)

(72) Inventor: Jerry S. Lin, Piedmont, CA (US)

(21) Appl. No.: 14/506,572

(22) Filed: Oct. 3, 2014

Related U.S. Application Data
(60) Provisional application No. 61/886,489, filed on Oct. 3, 2013.

(51) Int. Cl. F21V 29/00; F21K 99/00; H05K 7/20; F28F 3/02

(52) U.S. Cl. CPC F21V 29/2206; F28F 3/02; F21K 9/30; H05K 7/20127; H05K 7/2039; F21Y 2101/02
USPC 362/249.02; 29/890.03; 361/692

(57) ABSTRACT

A heat sink comprises skived fins and a base. The base has a first side and a second side. The skived fins are disposed on the first side, and at least one semiconductor device is mounted on the second side. The base has at least one channel for gas flow between the first side and the second side. The skived fins are formed by skiving segments from at least one layer of an alloy. The skived fins have one or more of the following patterns: a wavy skived pattern; a triangular skived pattern; and a block skived pattern.

### CROSS REFERENCE

This application claims priority from a provisional patent application entitled “LED Light Engine Heat Sink” filed on Oct. 3, 2013 and having an application Ser. No. 61/886,489. Said application is incorporated herein by reference.

### FIELD OF INVENTION

The disclosure relates to a heat sink, and, more particularly, to apparatuses for and methods of manufacturing a skived heat sink.

### BACKGROUND

Heat sinks are components or assemblies designed to transfer energy away from a device generating heat, e.g., semiconductor devices, including light emitting diodes (“LEDs”), central processing units (“CPUs”), graphics processing units (“GPUs”), and other electronic devices. Oftentimes, heat sinks make use of a liquid or gas to facilitate heat exchange to the surrounding environment. Some heat sinks used as a means for heat transfer include refrigeration systems, air conditioning systems, radiators, etc.

Semiconductor devices typically have heat sinks that pass air over a heat dissipation surface coupled to the semiconductor devices. The heat dissipation area is designed to increase heat transfer away from the heat generating devices, thereby cooling the semiconductor devices. Heat transfer can occur by way of convection. For a CPU, a highly conductive material having a fan thereon is typically mounted directly to the CPU. The fan forces air over the conductive material to increase the rate of convection. Without the fan, convection would otherwise occur naturally because hotter air near the material and CPU would rise relative to denser, cooler air. For example, as a processor heats the surrounding air, the warmer and less-dense air rises away from the processor and is replaced by the denser, cooler air. The process continues as cooler air continually replaces upwardly rising warmer air.

For lighting applications, LEDs are particularly energy efficient and tend to have a long operating life. LEDs may be employed in many different basic lighting structures to replace conventional neon or fluorescent lighting. More specifically, LED lighting assemblies may be deployed as street lights, automotive headlights or taillights, traffic and/or railroad signals, advertising signs, etc. These assemblies are typically exposed to natural environmental conditions and may be exposed to high ambient operating temperatures, especially during the daytime, in warmer climates, and in the summer. When coupled with the self-generated heat of the LEDs in the assembly, the resulting temperature within the assembly may adversely affect LED performance.

Heat sink design considerations have become increasingly important as LEDs are used in more powerful lighting assemblies that produce more heat energy. Heat dissipated in conventional LED assemblies has reached a critical level such that more intricate heat dissipation designs are needed to better regulate the self-generated heat within the LED assembly. The increased heat within the assemblies is mainly caused by substantially increasing the device drive current to achieve higher luminous output from the LEDs. Preferably, the internal temperature of the lamp assembly is maintained somewhat below the maximum operating temperature so the electrical components therein maintain peak performance. Accordingly, there is a constant need for improved thermal management solutions for LED-based lighting systems.

Therefore, there exists a need for new heat sinks and methods of manufacturing thereof that are highly efficient and robust in an indoor environment, as well as in an outdoor environment.

### SUMMARY OF INVENTION

Briefly, the disclosure relates to a heat sink, comprising: skived fins; and a base having a first side and a second side, wherein the skived fins are disposed on the first side, wherein at least one semiconductor device is mounted on the second side, and wherein the base having at least one channel for gas flow between the first side and the second side. The skived fins are formed by skiving an alloy. The skived fins are configured to be substantially perpendicular to the base of the heat sink. The skived fins have one or more of the following patterns: a wavy skived pattern; a triangular skived pattern; and a block skived pattern.

### DESCRIPTION OF THE DRAWINGS

The foregoing and other aspects of the disclosure can be better understood from the following detailed description of the embodiments when taken in conjunction with the accompanying drawings.

FIG. 1 illustrates a side view of a heat sink having skived fins and channels for gas flow.

FIG. 2 illustrates a bottom view of a heat sink having skived fins and channels for gas flow.

FIG. 3 illustrates a top view of a heat sink having patterned skived fins.

FIG. 4 illustrates a top view of an alternate embodiment of a heat sink having patterned skived fins.

FIG. 5 illustrates a top view of yet another alternate embodiment of a heat sink having patterned skived fins.

FIGS. 6a-6d illustrate a method for manufacturing a heat sink having skived fins.

FIG. 7 illustrates a flow chart for manufacturing a heat sink having skived fins.

FIGS. 8a-8c illustrate another method for manufacturing a heat sink having skived fins.

FIG. 9 illustrates another flow chart for manufacturing a heat sink having skived fins.

### DETAILED DESCRIPTION OF THE EMBODIMENTS

In the following detailed description of the embodiments, reference is made to the accompanying drawings, which form a part hereof, and in which is shown by way of illustration of specific embodiments in which the disclosure may be practiced.

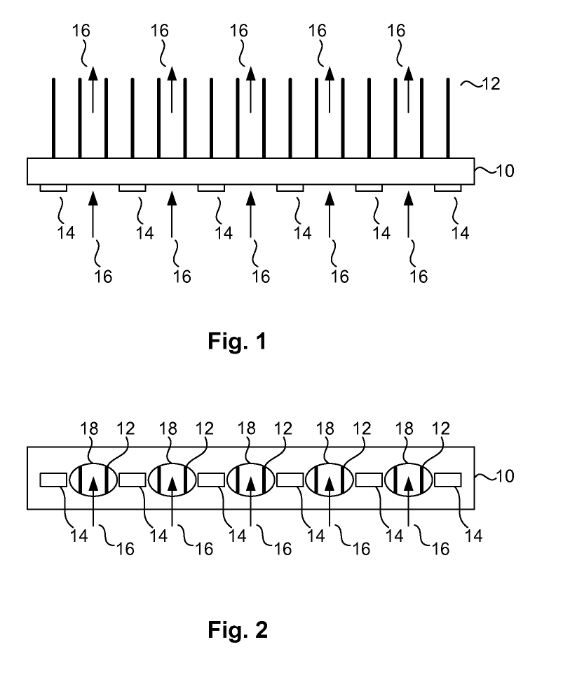

FIG. 1 illustrates a side view of a heat sink having skived fins and channels for gas flow. A heat sink comprises a base 10, skived fins 12, and one or more semiconductor devices 14. The base 10 can have one or more gas channels 18 (not shown) to allow gas flow 16 from one side of the base 10 to flow to the other side of the base 10 and vice versa. For instance, the semiconductor devices 14 can be disposed on a first side of the base 10 and the skived fins can be disposed on a second side of the base 10. The channels 18 can connect these two sides, and allow gas flow 16 to flow from the side of the semiconductor devices 14 to the other side having the skived fins 12. The gas flow 16 through the skived fins 12 allow for greater heat dissipation. Furthermore, the skived patterns of the skived fins 12 provide greater surface area for heat dissipation than non-patterned and flat fins.

FIG. 2 illustrates a bottom view of a heat sink having skived fins and channels for gas flow through the base. From a bottom view of the heat sink, the semiconductor devices 14 and the channels 18 are visible on the base 10. It is understood by a person having ordinary skill in the art that the configuration of the semiconductor devices and the channels of the heat sink can be varied. For instance, in other embodiments the channels may be smaller and spaced after every two semiconductor devices, rather than what is shown in FIG. 2. Alternatively, the number of semiconductor devices and configurations of the semiconductor devices can vary as well. In one embodiment, there can be two rows of six semiconductor devices that run across the base, with the channels disposed in the middle of the base between the two rows of semiconductor devices. To aid in the understanding of the present disclosure, a simplified configuration is presented, as shown in FIG. 2. However, the present disclosure is meant to cover all variations and configurations readily known to a person having ordinary skill in the art.

Since the channels 18 allow for gas flow between the two sides of the base 10, the skived fins 12 disposed on the other side of the base 10 can be seen through the channels 18 from the bottom view. Thereby, the gas flow 16 can easily flow between some of the skived fins 12 that are mounted on the other side of the channels 18. Furthermore, the channels 18 can have a screen or other mesh (not shown) such that objects (e.g., dust particles, rocks, etc.) are blocked from entering the channels 18.

The base 10 can be a thermal spreader for allowing any heat from the semiconductor devices 14 to spread to the skived fins 12. For instance, the base 10 and the skived fins 12 can be composed of a pure metal or metal alloy, including copper, silver, copper, tungsten, aluminum, titanium, steel, bronze, brass, etc., and combinations thereof. Furthermore, the base 10 can comprise multiple layers (not shown). A first one of the layers can have traces or wires for routing power to the semiconductor devices 14, and can be used for mounting and securing the semiconductor devices 14 to the layer. A second one of the layers can be disposed next to that first layer to spread the heat from the semiconductor devices 14 to the skived fins 12. The second one of the layers and the skived fins 12 can also be made from the same metal object such that the second layer and the skived fins 12 are connected together. In other embodiments, the skived fins 12 can be separate pieces that are joined to the second layer. The skived fins 12 and the second layer of the base 10 can be joined together by a bonding compound or by other joining methods.

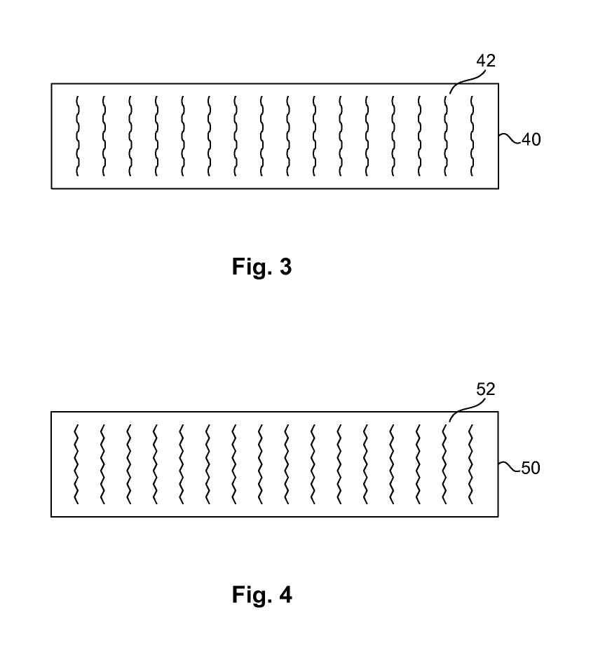

FIG. 3 illustrates a top view of a heat sink having patterned skived fins. Typically, skiving is used to shave off a flat sheet from a material, e.g., cow hide or other fabrics. The skiver has a sharp and flat razor that contacts the material. The flat razor runs along the surface of the material to shave off a flat sheet of the material. In the present disclosure, the razor has a pattern that is translated to the skived sheet. When the material is an alloy (or other rigid body), the skived alloy sheet (or layer, or sheet) retains the patterned shape of the razor since the skived alloy sheet is also rigid. The skived alloy sheet can serve as skived fins, where the thinness of the skived fins can be lesser than other manufactured fins due in large part to the skiving method for manufacturing the skived alloy sheet.

The skived fins can have various skived patterns, including a wavy skived pattern, a triangular skived pattern, a block skived pattern, or some other non-flat skived pattern. Referring to FIG. 3, in a top view of a heat sink 40, the pattern of skived fins 42 disposed on the heat sink 40 can be a wavy skived pattern.

FIG. 4 illustrates a top view of an alternate embodiment of a heat sink having patterned skived fins. In a top view of a heat sink 50, the pattern of skived fins 52 disposed on the heat sink 40 can be a triangular skived pattern.

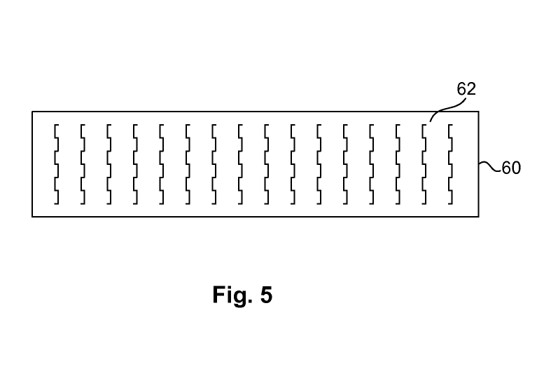

FIG. 5 illustrates a top view of yet another embodiment of a heat sink having patterned skived fins. In a top view of a heat sink 60, the pattern of skived fins 62 disposed on the heat sink 60 can be a block skived pattern.

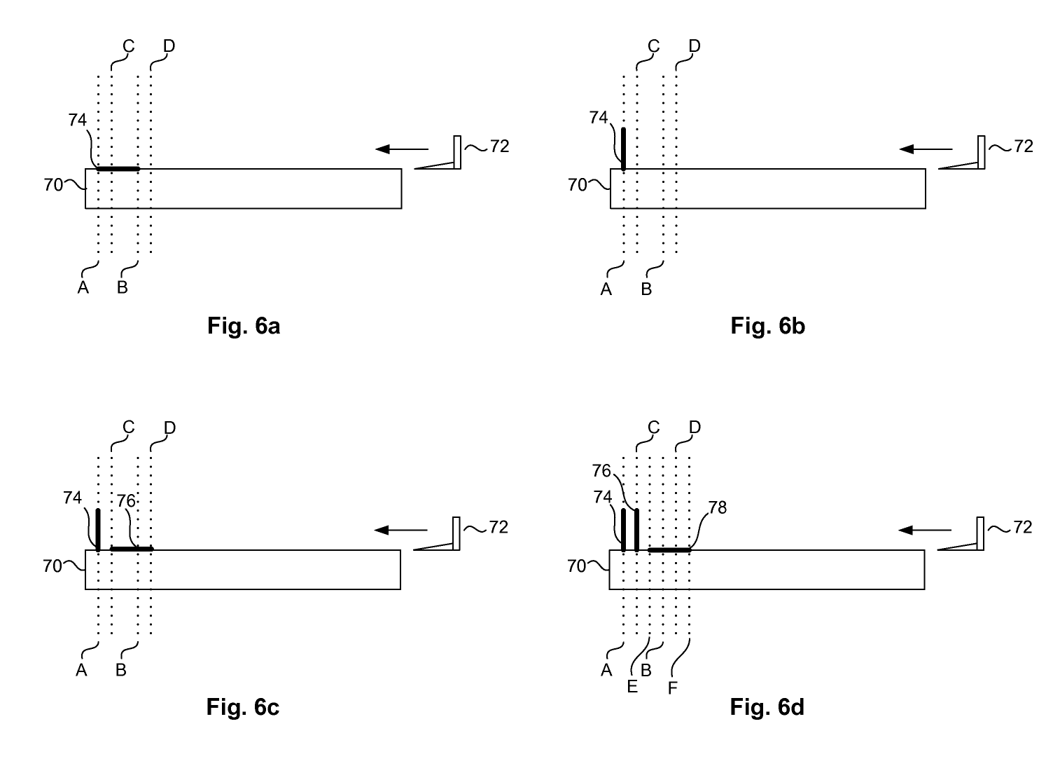

FIGS. 6a-6d illustrate a method for manufacturing a heat sink having skived fins. An alloy 70 can be skived to generate the skived fins and a layer of the base (or the entire base) of a heat sink. A skiver 72 can be a skiving machine having a patterned razor to skive the alloy 70. The skiver 72 makes multiple passes along the alloy with each pass cutting a fin's length from the alloy 70 to form a single skived fin. During each pass, the skiver 72 does not completely sever the skived fin from the block 70, but keeps a base portion of the skived fin connected to the alloy 70. At every additional pass, the skiver 72 cuts further along the alloy 70 such that multiple fins are generated along the alloy 70. The skived fins can be equidistant from each other.

For instance, the skiver 72 can start at a point B and cut the alloy 70 to point A to form a first skived fin 74. The skiver 72 does not sever the skived fin 74 from the alloy 70, leaving the skived fin 74 connected at its base to the alloy 70. After the skiver 72 cuts the skived fin 74, the skiver 72 bends the skived fin 74 at its base to a vertical position (see FIG. 6b), such that the skived fin 74 is substantially perpendicular to the alloy 70.

Referring to FIG. 6c, on a second pass, the skive 72 can start at point D and cut the alloy 70 to point C to form a second skived fin 76. The skiver 72 does not sever the skived fin 76 from the alloy 70, leaving the skived fin 74 connected at its base to the alloy 70. After the skiver 72 cuts the skived fin 76, the skiver 72 bends the skived fin 76 at its base to a vertical position (see FIG. 6d), such that the skived fin 76 is substantially perpendicular to the alloy 70.

The skiver 72 continues along a path on the alloy 70 cutting additional skived fins (e.g., a skived fin 78, illustrated in FIG. 6d). The skived fins 74, 76, and 78 and any additional skived fins can be equidistant from its neighboring fins to form a uniform appearing skived fin configuration. In such configuration, the starting points of the skiver 72 (e.g., points B, D, F, etc.) are at equal intervals from each other. The ending points of the skiver 72 (e.g., points A, C, E, etc.) are also at equal intervals from each other.

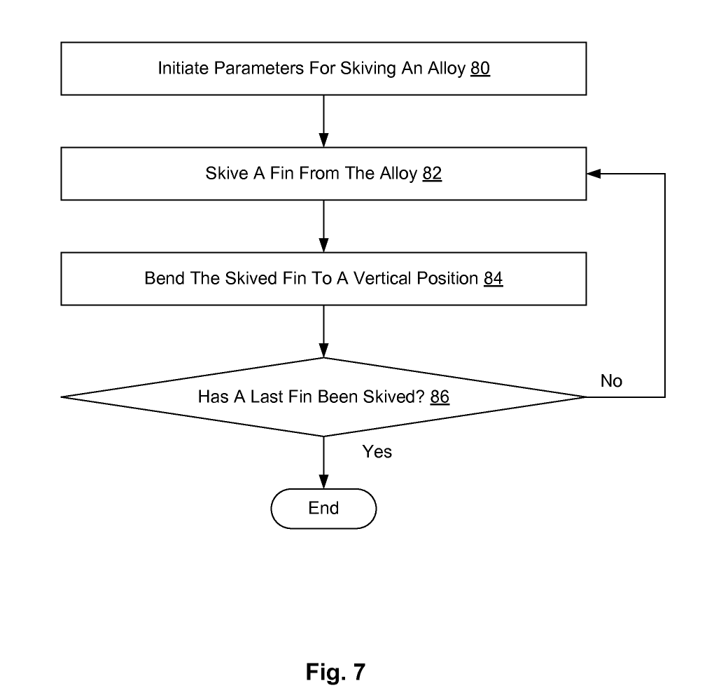

FIG. 7 illustrates a flow chart for manufacturing a heat sink having skived fins. A heat sink can be manufactured by first initiating parameters for skiving an alloy 80. The parameters can be one or more of the following: the size of the alloy; the distance between fins on the alloy; the width of the fins; the height of the fins; the number of total fins to be skived on the alloy; whether the skived fins are to be severed from the alloy or not severed from the alloy; and other parameters for skiving the alloy. Next, a fin is skived from the alloy 82. The fin is then bent to a vertical position (i.e., substantially perpendicular to the skived surface of the alloy) 84. A determination is made as to whether the last fin has been skived 86. If the last fin of the alloy is skived, then the process is ended. If not, the process restarts at skiving a next fin from the alloy 82. This process continues until all the skived fins have been skived.

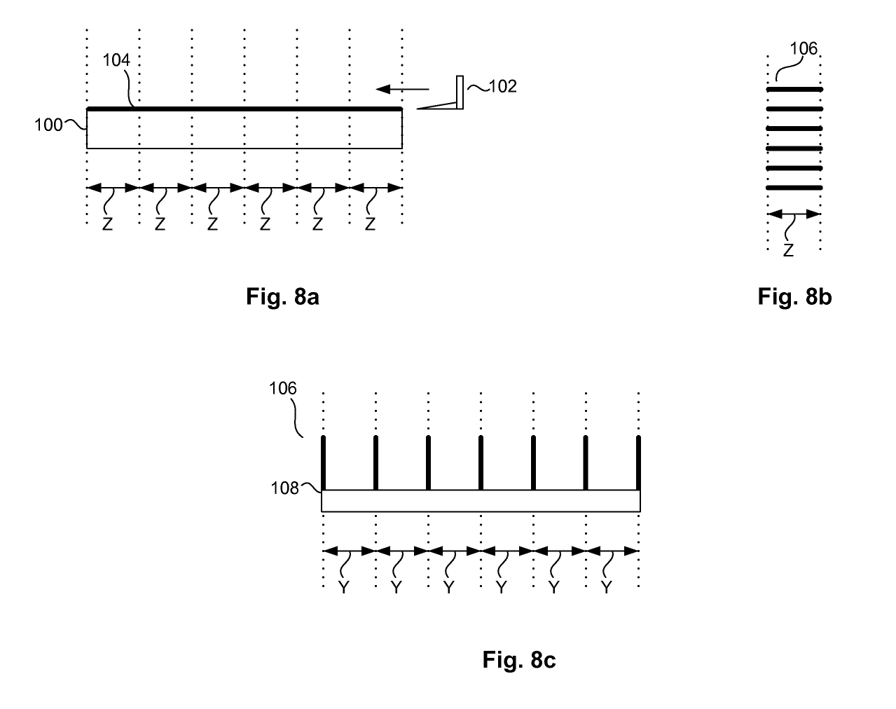

FIGS. 8a-8c illustrates another method for manufacturing a heat sink having skived fins. An alloy 100 can be partitioned into fin segments of a length z. A patterned skiver 102 can skive a layer 104 of the alloy 100 having the skived fin segments (see FIG. 8a). The layer 104 can be further cut into skived fins 106 by cutting the segment endpoints to have multiple distinct skived fins (see FIG. 8b). Next, the skived fins 106 are bonded to a base 108 of the heat sink 106. The skived fins 106 can be bounded to the base 108, where the skived fins 106 are spaced a distance Y from each other on the base 108. The bonding can be from soldering, adhesive bonding, thermo-compression, chemical bonding, or other bonding methods to bond the skived fins 106 to the base 108. In certain embodiments, the base 108 can be the remaining alloy 100. Thus in such example, the skived fins 106 are bonded to the remaining alloy 100.

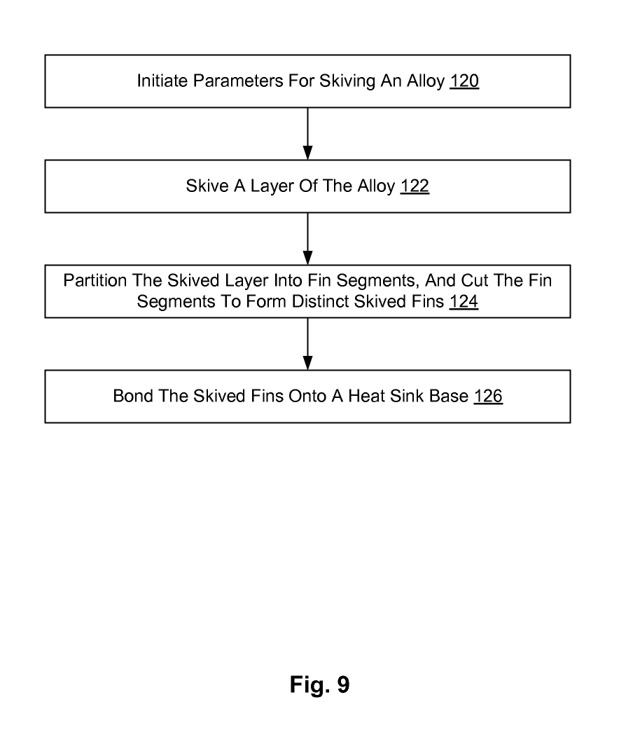

FIG. 9 illustrates another flow chart for manufacturing a heat sink having skived fins. A heat sink can be manufactured by first initiating parameters for skiving an alloy 120. The parameters can be one or more of the following: the size of the alloy; the distance between fins on the alloy; the width of the fins; the height of the fins; the number of total fins to be skived on the alloy; whether the skived fins are to be severed from the alloy or not severed from the alloy; and other parameters for skiving the alloy. Next, a layer of the alloy is skived 122. The skived layer is then partitioned into fin segments, and the fin segments are cut at their endpoints to generate distinct skived fins 124. Lastly, the skived fins are bonded onto the base of the heat sink 126.

While the disclosure has been described with reference to certain embodiments, it is to be understood that the disclosure is not limited to such embodiments. Rather, the disclosure should be understood and construed in its broadest meaning, as reflected by the following claims.

Thus, these claims are to be understood as incorporating not only the apparatuses, methods, and systems described herein, but all those other and further alterations and modifications as would be apparent to those of ordinary skilled in the art.

We Claim:

1. A heat sink, comprising:
skived fins; and
a base having a first side and a second side,
wherein the skived fins are disposed on the first side,
wherein at least one semiconductor device is mounted on the second side,
wherein the base having at least one channel for gas flow between the first side and the second side, and
wherein the skived fins have one or more of the following patterns: a wavy skived pattern; a triangular skived pattern; and a block skived pattern.

2. The heat sink of claim 1 wherein the skived fins are formed by skiving an alloy, and wherein the skived fins are configured to be substantially perpendicular to the base.

3. The heat sink of claim 1 wherein at least one of the skived fins is partially disposed over the channel.

4. The heat sink of claim 1 wherein there are a plurality of channels and a plurality of semiconductor devices, wherein the plurality of semiconductor devices are light-emitting-diodes (“LEDs”), and wherein between any two or more of the LEDs, there is at least one of the channels.

5. A method for manufacturing a heat sink having skived fins and a base, comprising the steps of:
initiating parameters for skiving an alloy;
skiving one or more fins from the alloy to form the skived fins; and
configuring the skived fins to a substantially perpendicular position to the base,
wherein the skived fins have one or more of the following patterns: a wavy skived pattern; a triangular skived pattern; and a block skived pattern.

6. The method of claim 5 wherein the alloy is partitioned into fin segments, wherein, in the skiving step, each of the fin segments are separately skived by a skiver to form the skived fins, and wherein the skived fins are partially intact with the alloy after skiving.

7. The method of claim 5 wherein the skived fins are bent to a substantially vertical position.

8. The method of claim 5 wherein in the configuring step, the remaining alloy is the base.

9. The method of claim 5 wherein the alloy is partitioned into fin segments, wherein, in the skiving step, the alloy is skived in a single cut forming an alloy layer, and wherein the skived layer is cut at each end point of the fin segments to form the skived fins.

10. The method of claim 5 wherein the skived fins are bonded to the base.

11. The method of claim 5 wherein the skived fins have one or more of the following patterns: a wavy skived pattern; a triangular skived pattern; and a block skived pattern.

12. A heat sink, comprising:
skived fins, wherein the skived fins are formed by skiving an alloy; and
a base having a first side and a second side,
wherein the skived fins are disposed on the first side,
wherein the skived fins are configured to be substantially perpendicular to the base,
wherein light emitting diodes (“LEDs”) are mounted on the second side,
wherein the base having channels for gas flow between the first side and the second side,
wherein at least one of the skived fins is partially disposed over at least one of the channels,
wherein the skived fins have one or more of the following patterns: a wavy skived pattern; a triangular skived pattern; and a block skived pattern, and
wherein between any two or more of the LEDs, there is at least one of the channels.
